(19) United States
(12) Patent Application Publication
(10) Pub. No.: US 2022/0282100 A1
(43) Pub. Date: Sep. 8, 2022

(54) METAL OXIDE FILM-FORMING COMPOSITION, AND METHOD FOR PRODUCING METAL OXIDE FILM USING THE SAME

(71) Applicant: TOKYO OHKA KOGYO CO., LTD., Kawasaki-shi (JP)

(72) Inventors: Kunihiro NODA, Kawasaki-shi (JP); Kenichi YAMAUCHI, Kawasaki-shi (JP); Naohiko IKUMA, Kawasaki-shi (JP); Dai SHIOTA, Kawasaki-shi (JP)

(21) Appl. No.: 17/652,011

(22) Filed: Feb. 22, 2022

(30) Foreign Application Priority Data
Feb. 26, 2021 (JP) 2021-030462

(51) Int. Cl. C09D 7/63; C01G 23/04; C01G 25/02; C09D 1/00

(52) U.S. Cl. CPC C09D 7/63; C01G 23/04; C01G 25/02; C09D 1/00

(57) ABSTRACT

A metal oxide film-forming composition containing an organooxy group-containing aromatic hydrocarbon ring-modified fluorene compound represented by formula (1), a metal compound represented by formula L(R⁶)ₙ₁(O)ₙ₂, and a solvent. In the formulas, ring Z¹ represents an aromatic hydrocarbon ring, R₁ₐ and R^{1b} each represents a halogen atom, a cyano group, or an alkyl group, R^{2a} and R^{2b} each represents an alkyl group, R^{3a} and R^{3b} each represents a tertiary alkyloxycarbonyl group, k1 and k2 each represent an integer between 0 and 4 inclusive, m1 and m2 each represent an integer between 0 and 6 inclusive, R⁶ represents OR⁷, R⁷ represents an organic group having 1 to 30 carbon atoms, n1 and n2 each represent an integer of 0 or larger, n1+2×n2 is a valence depending on the type of L, and L represents Al, Ga, Y, Ti, Zr, Hf, Bi, Sn, V, or Ta

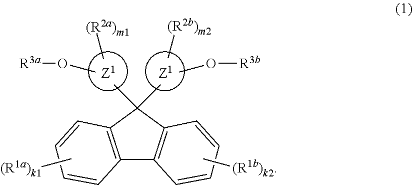

### RELATED APPLICATION

This application claims priority to Japanese Patent Application No. 2021-030462, filed Feb. 26, 2021, the entire content of which is incorporated herein by reference.

### BACKGROUND OF THE INVENTION

### Field of the Invention

The present invention relates to a metal oxide film-forming composition, and a method for producing a metal oxide film using the composition.

### Related Art

High refractive index materials are used in formation of optical components. As the high refractive index material, for example, materials obtained by dispersing metal oxide particles such as titanium oxide and zirconium oxide in an organic component are used. As such a high refractive index material, a composition containing metal oxide particles and a fluorene compound having a specific structure including a hydrolyzable silyl group in which a benzene ring is bonded to fluorene has been disclosed (see Patent Document 1). Since the composition in Patent Document 1 contains the fluorene compound having the specific structure including the hydrolyzable silyl group in which the benzene ring is bonded to the fluorene, the composition has a high refractive index and is excellent in a metal oxide particle dispersibility.
Patent Document 1: Japanese Unexamined Patent Application, Publication No. 2012-233142

### SUMMARY OF THE INVENTION

From investigation by the present inventors, it has found that conventional metal oxide film-forming compositions containing metal oxide particles are poor in dispersion stability in some cases, and that metal oxide films obtained by heating the metal oxide film-forming compositions are poor in any of film thickness uniformity, refractive index, and heat resistance.

The present invention has been made in view of such conventional circumstances, and an object of the present invention is to provide a metal oxide film-forming composition excellent in dispersion stability and obtains a metal oxide film having excellent film thickness uniformity, refractive index and heat resistance after heating, and a method for producing a metal oxide film using the composition.

The present inventors have made intensive investigations in order to solve the above problems. As a result, it has found that the above problems can be solved by a metal oxide film-forming composition containing a predetermined organooxy group-containing aromatic hydrocarbon ring-modified fluorene compound, a predetermined metal compound, and a solvent, and this finding has led to the completion of the invention. Specifically, the present invention provides the followings.

A first aspect of the invention is directed to a metal oxide film-forming composition including: an organooxy group-containing aromatic hydrocarbon ring-modified fluorene compound represented by the following formula (1); a metal compound represented by the following formula (2); and a solvent.

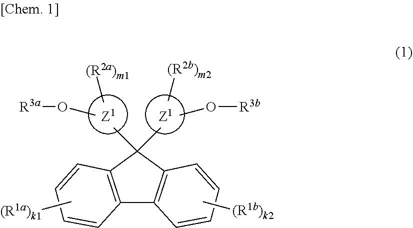

In formula (1),
ring Z¹ represents an aromatic hydrocarbon ring,
R^{1a} and R^{1b} each independently represent a halogen atom, a cyano group, or an alkyl group,
R^{2a} and R^{2b} each independently represent an alkyl group,
R^{3a} and R^{3b} are each independently a group represented by the following formula (3), (4), (5), or (6),
k1 and k2 each independently represent an integer of 0 or larger to 4 or smaller, and
m1 and m2 each independently represent an integer of 0 or larger to 6 or smaller.

L(R⁶)ₙ₁(O)ₙ₂ (2)

In formula (2), R⁶ represents a group represented by OR⁷, R⁷ represents an organic group having 1 to 30 carbon atoms, and n1 and n2 each independently represent an integer of 0 or larger, provided that n1+2×n2 is a valence depending on the type of L, and L represents aluminum, gallium, yttrium, titanium, zirconium, hafnium, bismuth, tin, vanadium, or tantalum.

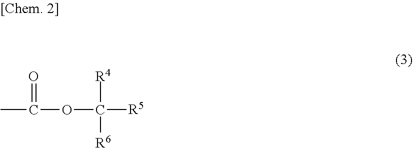

In formula (3), R⁴, R⁵ and R⁶ each independently represent an alkyl group having 1 to 8 carbon atoms.

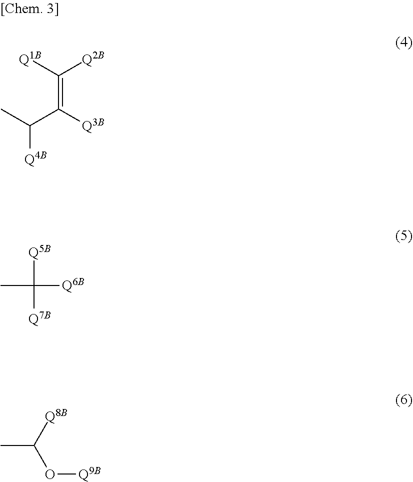

In the formula, Q^{1B} to Q^{4B} are each a hydrogen atom or an alkyl group having 1 to 20 carbon atoms, and any two substituents selected from Q^{1B} to Q^{4B} may be bonded to each other to form a cyclic substituent. Q^{5B} to Q^{7B} are each an alkyl group having 1 to 20 carbon atoms, and any two substituents selected from Q^{5B} to Q^{7B} may be bonded to each other to form a cyclic substituent. Q^{8B} and Q^{9B} are each an alkyl group having 1 to 20 carbon atoms, and Q^{8B} and Q^{9B} may be bonded to each other to form a cyclic substituent.

A second aspect of the present invention is directed to a method for producing a metal oxide film, including a coating film-forming step of forming a coating film composed of the metal oxide film-forming composition according to the first aspect, and

a heating step of heating the coating film.

According to the present invention, it is possible to provide a metal oxide film-forming composition excellent in dispersion stability and obtains a metal oxide film having excellent film thickness uniformity, refractive index and heat resistance after heating, and a method for producing a metal oxide film using the composition.

### DETAILED DESCRIPTION OF THE INVENTION

### <Metal Oxide Film-Forming Composition>

The metal oxide film-forming composition according to the present invention contains the organooxy group-containing aromatic hydrocarbon ring-modified fluorene compound represented by the above formula (1), the metal compound represented by the above formula (2), and a solvent. The metal oxide film-forming composition according to the present invention is excellent in dispersion stability and can obtain a metal oxide film having excellent film thickness uniformity, refractive index and heat resistance after heating.

### [Organooxy Group-Containing Aromatic Hydrocarbon Ring-Modified Fluorene Compound Represented by Formula (1)]

The metal oxide film-forming composition contains the organooxy group-containing aromatic hydrocarbon ring-modified fluorene compound represented by the above formula (1). The organooxy group-containing aromatic hydrocarbon ring-modified fluorene compound may be used alone or in combination of two or more types thereof.

In the above formula (1), examples of the aromatic hydrocarbon ring represented by ring Z¹ include, but are not particularly limited to, a naphthalene ring and a benzene ring.

Specific examples of the halogen atom as R^{1a} and R^{1b} in the above formula (1) include chlorine atom, fluorine atom, bromine atom, and iodine atom. In the above formula (1), the alkyl group as R^{1a} and R^{1b} may be linear or branched chain, and examples of the alkyl group include alkyl groups having 1 or more to 6 or less carbon atoms, such as a methyl group, an ethyl group, a propyl group, an isopropyl group, a butyl group, and a tert-butyl group. R^{1a} and R^{1b} may be the same as or different from each other. When k1 is an integer of 2 or larger, two or more groups R^{1a} may be the same as or different from each other, and when k2 is an integer of 2 or larger, two or more groups R^{1b} may be the same as or different from each other. k1 and k2 are each independently an integer of 0 or larger to 4 or smaller, preferably 0 or 1, more preferably 0. k1 and k2 may be the same as or different from each other.

In the above formula (1), the alkyl group as R^{2a} and R^{2b} may be linear or branched chain, and examples of the alkyl group include alkyl groups having 1 or more to 18 or less carbon atoms, such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group, preferably an alkyl group having 1 or more to 8 or less carbon atoms, more preferably an alkyl group having 1 or more to 6 or less carbon atoms. R^{2a} and R^{2b} may be the same as or different from each other. When m1 is 2, two groups R^{2a} may be the same as or different from each other, and when m2 is 2, two groups R^{2b} may be the same as or different from each other. m1 and m2 are each independently an integer of 0 or larger to 6 or smaller, preferably an integer of 0 or larger to 3 or smaller, more preferably 0 or 1. m1 and m2 may be the same as or different from each other.

In the above formula (1), R^{3a} and R^{3b} are each independently the group represented by the above formula (3), (4), (5) or (6). In terms of the refractive index, the heat resistance, and the like of the obtained metal oxide film, the group represented by the above formula (3) is preferable.

In the above formula (3), examples of the alkyl groups having 1 to 8 carbon atoms represented by R⁴, R⁵ and R⁶ include, but are not particularly limited to, a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an n-octyl group, and the like. In terms of synthesis easiness, stability, and the like, an alkyl group having 1 or more to 6 or less carbon atoms, such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group is preferable, an alkyl group having 1 or more to 3 or less carbon atoms, such as a methyl group, an ethyl group, a propyl group, an isopropyl group is more preferable, and a methyl group is even more preferable.

In the above formula (4), examples of the alkyl groups having 1 to 20 carbon atoms represented by Q^{1B} to Q⁴B include, but are not particularly limited to, include a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an n-octyl group, an n-decyl group, an n-dodecyl group, an n-octadecyl group, an n-icosyl group, and the like. In terms of synthesis easiness, stability, and the like, an alkyl group having 1 or more to 6 or less carbon atoms, such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group is preferable, an alkyl group having 1 or more to 3 or less carbon atoms, such as a methyl group, an ethyl group, a propyl group, and an isopropyl group is more preferable, and a methyl group and an ethyl group are even more preferable.

Examples of a cyclic substituent formed by the bonding between any two substituents selected from Q^{1B} to Q^{4B} include a group formed by removing two or three hydrogen atoms from a cycloalkane ring, a cycloalkene ring, or a crosslinked carbon ring, a group formed by removing two hydrogen atoms from an aromatic hydrocarbon ring, and the like.

In the above formula (5), examples of the alkyl groups having 1 to 20 carbon atoms represented by Q^{5B} to Q^{7B} include, but are not particularly limited to, a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an n-octyl group, an n-decyl group, an n-dodecyl group, an n-octadecyl group, an n-icosyl group, and the like.

In terms of synthesis easiness, stability, and the like, an alkyl group having 1 or more to 6 or less carbon atoms, such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group is preferable, an alkyl group having 1 or more to 3 or less carbon atoms, such as a methyl group, an ethyl group, a propyl group, and an isopropyl group is more preferable, and a methyl group and an ethyl group are even more preferable.

Examples of a cyclic substituent formed by the bonding between any two substituents selected from Q^{5B} to Q^{7B} include a group formed by removing two hydrogen atoms from a cycloalkane ring, a cycloalkene ring, or a crosslinked carbon ring, and the like.

In the above formula (6), examples of the alkyl groups having 1 to 20 carbon atoms represented by Q^{8B} and Q^{9B} include, but are not particularly limited to, a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an n-octyl group, an n-decyl group, an n-dodecyl group, an n-octadecyl group, an n-icosyl group, and the like.

In terms of synthesis easiness, stability, and the like, an alkyl group having 1 or more to 6 or less carbon atoms, such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group is preferable, an alkyl group having 1 or more to 3 or less carbon atoms, such as a methyl group, an ethyl group, a propyl group, and an isopropyl group is more preferable, and a methyl group and an ethyl group are even more preferable.

Examples of a cyclic substituent formed by the bonding between Q^{8B} and Q^{9B} include a group formed by removing one hydrogen atom from, for example, a cyclic ether compound, and the like.

Examples of the organooxy group-containing aromatic hydrocarbon ring-modified fluorene compound represented by formula (1) include an organooxy group-containing aromatic hydrocarbon ring-modified fluorene compound represented by the following formula (1-1), an organooxy group-containing aromatic hydrocarbon ring-modified fluorene compound represented by the following formula (1-2), and the like. Note that, in formula (1-1), R^{2a}, R^{2b}, —O—R^{3a}, and —O—R^{3b} bonded to a naphthalene ring is bonded to a 6-membered ring not bonded to a fluorene ring among two 6-membered rings constituting the naphthalene ring.

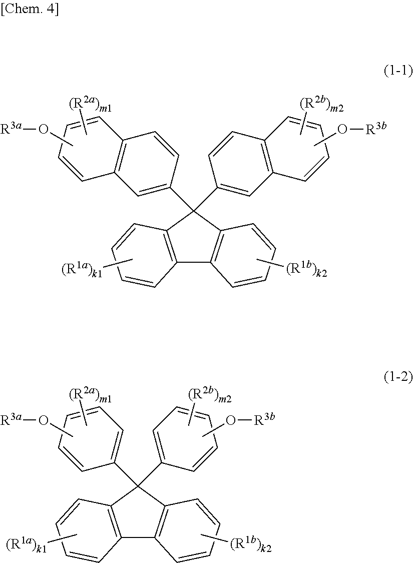

wherein R^{1a}, R^{1b}, R^{2a}, R^{2b}, R^{3a}, R^{3b}, k1, k2, ml, and m2 are as described above.

Specific examples of the organooxy group-containing aromatic hydrocarbon ring-modified fluorene compound represented by formula (1) are as below, but are not limited to the followings.

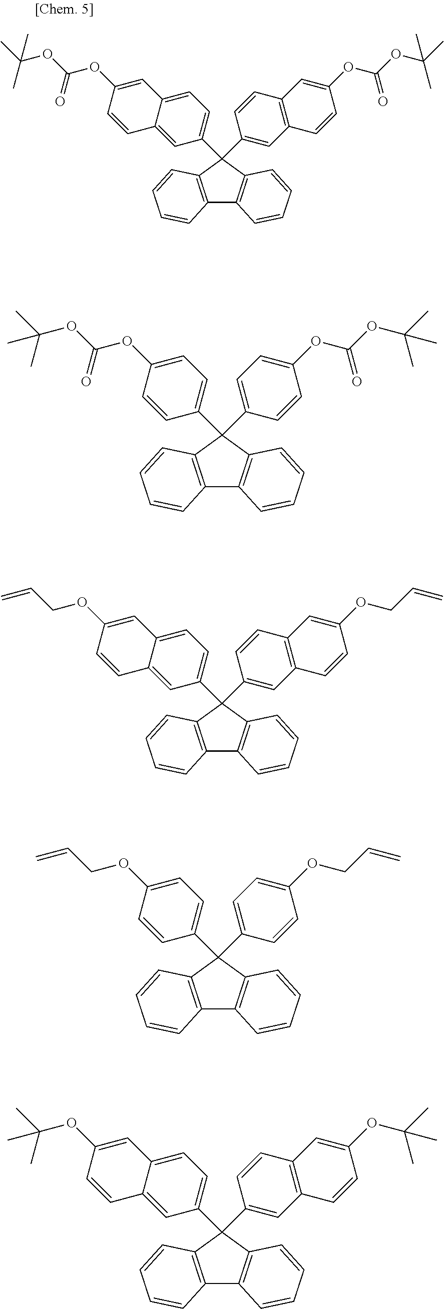

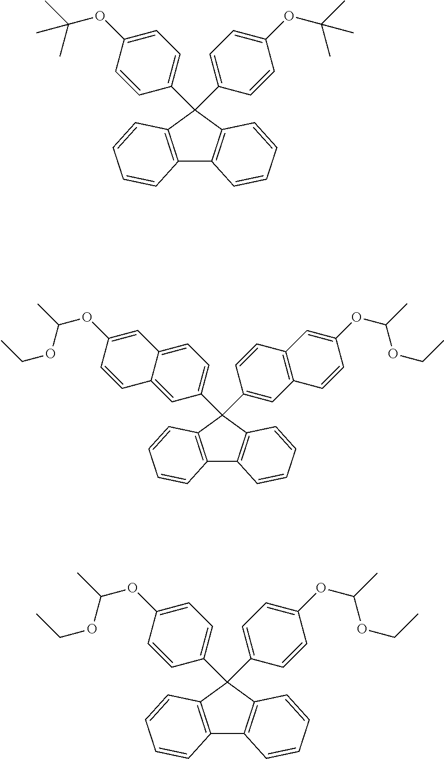

The organooxy group-containing aromatic hydrocarbon ring-modified fluorene compound represented by the above formula (1) can be produced using any organic synthesis reaction.

When R^{3a} and R^{3b} are the group represented by the above formula (3), the organooxy group-containing aromatic hydrocarbon ring-modified fluorene compound represented by the above formula (1) can be produced e.g. by reacting a hydroxy group-containing aromatic hydrocarbon ring-modified fluorene compound represented by the following formula (7) with a di(tertiary alkyl) dicarbonate compound represented by the following formula (8) in the presence of a base (e.g. an organic base such as triethylamine, pyridine, and N,N-dimethyl-4-aminopyridine) in a solvent (e.g. an alkyl halide-based solvent such as dichloromethane, an ether-based solvent such as tetrahydrofuran (THF), an alcohol-based solvent such as methanol).

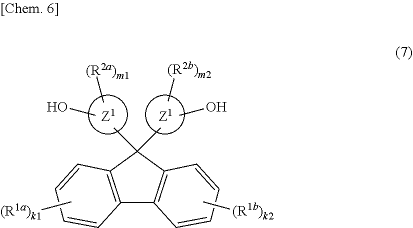

wherein Z¹, R^{1a}, R^{1b}, R^{2a}, R^{2b}, k1, k2, ml, and m2 are as described above.

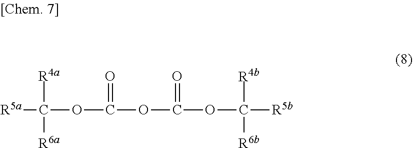

wherein R^{4a}, R^{4b}, R^{5a}, R^{5b}, R^{6a}, and R^{6b} each independently represent an alkyl group having 1 to 8 carbon atoms.

When R^{3a} and R^{3b} are the group represented by the above formula (4), the organooxy group-containing aromatic hydrocarbon ring-modified fluorene compound represented by the above formula (1) can be produced e.g. by reacting the hydroxy group-containing aromatic hydrocarbon ring-modified fluorene compound represented by the above formula (7) with a compound represented by the following formula (4-1) in the presence of a base (e.g. an inorganic base such as potassium carbonate) in a solvent (e.g. a ketone-based solvent such as acetone).

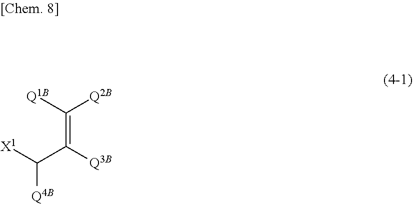

wherein X¹ represents a halogen atom such as chlorine atom, fluorine atom, bromine atom, and iodine atom, and Q^{1B} to Q^{4B} are as described above.

When R^{3a} and R^{3b} are the group represented by the above formula (5), the organooxy group-containing aromatic hydrocarbon ring-modified fluorene compound represented by the above formula (1) can be produced e.g. by reacting an oxygen-containing group-containing aromatic hydrocarbon ring-modified fluorene compound represented by the following formula (9) with a compound represented by the following formula (5-1) in the presence of a catalyst (e.g. an acid catalyst such as concentrated sulfuric acid) in a solvent (e.g. an alkyl halide-based solvent such as dichloromethane).

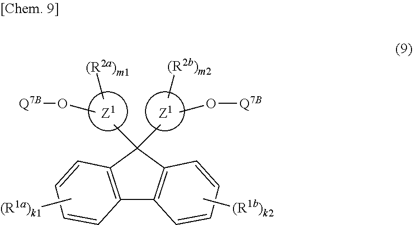

wherein Z¹, R^{1a}, R^{1b}, R^{2a}, R^{2b}, k1, k2, m1, m2, and Q^{7b} are as described above.

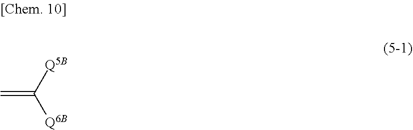

wherein Q^{5b} and Q^{6b} are as described above.

When R^{3a} and R^{3b} are the group represented by the above formula (6), the organooxy group-containing aromatic hydrocarbon ring-modified fluorene compound represented by the above formula (1) can be produced e.g. by reacting the hydroxy group-containing aromatic hydrocarbon ring-modified fluorene compound represented by the above formula (7) with a compound represented by the following formula (6-1) in the presence of a catalyst (e.g. an acid catalyst such as p-toluenesulfonic acid) in a solvent (e.g. an ether-based solvent such as diethyl ether).

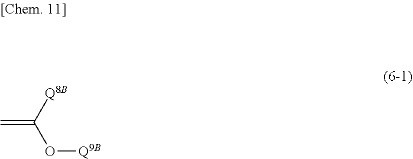

wherein Q^{8B} and Q^{9B} are as described above.

A usage amount of the organooxy group-containing aromatic hydrocarbon ring-modified fluorene compound represented by the above formula (1) is not particularly limited, and is, for example, 30 to 70% by mass, preferably 40 to 60% by mass based on the total amount of components other than the solvent in the metal oxide film-forming composition. When the usage amount of the organooxy group-containing aromatic hydrocarbon ring-modified fluorene compound is within the above range, the film thickness uniformity of the obtained metal oxide film is easily improved.

### [Metal Compound Represented by Formula (2)]

The metal oxide film-forming composition contains the metal compound represented by the above formula (2). The metal compound may be used alone or in combination of two or more types thereof.

In the above formula (2), when n1 represents an integer of 2 or larger, the plurality of groups R⁶ may be the same as or different from each other.

In the above formula (2), examples of the organic group having 1 to 30 carbon atoms represented by R⁷ include, but are not particularly limited to, an alkyl group having 1 to 30 carbon atoms, a cycloalkyl group having 3 to 30 carbon atoms, an alkenyl group having 2 to 30 carbon atoms, an aryl group having 6 to 30 carbon atoms, and an alkoxyalkyl group having 2 to 30 carbon atoms.

Examples of the alkyl group having 1 to 30 carbon atoms include, but are not particularly limited to, a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, a tert-hexyl group, an n-heptyl group, an n-octyl group, an n-decyl group, an n-dodecyl group, an n-octadecyl group, an n-icosyl group, and the like. In terms of synthesis easiness, stability, and the like, an alkyl group having 1 or more to 6 or less carbon atoms such as a methyl group, an ethyl group, a propyl group, an isopropyl group, a butyl group, a tert-butyl group, an n-pentyl group, an isopentyl group, a sec-pentyl group, a tert-pentyl group, an n-hexyl group, an isohexyl group, a sec-hexyl group, and a tert-hexyl group is preferable.

Examples of the cycloalkyl group having 3 to 30 carbon atoms include, but are not particularly limited to, a cyclopropyl group, a cyclobutyl group, a cyclopentyl group, a cyclohexyl group, a cycloheptyl group, a cyclooctyl group, a cyclodecyl group, a cyclododecyl group, a cyclooctadecyl group, a cycloicosyl group, and the like. In terms of synthesis easiness, stability, and the like, a cycloalkyl group having 3 or more to 6 or less carbon atoms, such as a cyclopropyl group, a cyclobutyl group, a cyclopentyl group, and a cyclohexyl group is preferable.

Examples of the alkenyl group having 2 to 30 carbon atoms include, but are not particularly limited to, a vinyl group, an allyl group, and the like. In terms of synthesis easiness, stability, and the like, the allyl group is preferable.

Examples of the aryl group having 6 to 30 carbon atoms include, but are not particularly limited to, a phenyl group, a naphthyl group, and the like. In terms of synthesis easiness, stability, and the like, the phenyl group is preferable.

Examples of the alkoxyalkyl group having 2 to 30 carbon atoms include, but are not particularly limited to, a methoxymethyl group, a methoxyethyl group, an ethoxymethyl group, an ethoxyethyl group, and the like. In terms of synthesis easiness, stability, and the like, the methoxyethyl group and the ethoxyethyl group are preferable.

In the above formula (2), for example, R⁶ is represented by OR⁷, and examples of R⁷ include the alkyl group having 1 to 30 carbon atoms, the cycloalkyl group having 3 to 30 carbon atoms, the alkenyl group having 2 to 30 carbon atoms, the aryl group having 6 to 30 carbon atoms, the alkoxyalkyl group having 2 to 30 carbon atoms, as well as an alkylacetoacetate group having 5 to 30 carbon atoms, a 2,4-pentanedionato group (i.e. acetylacetonato group), a 2,2,6,6-tetramethyl-3,5-heptanedionato group.

Examples of the alkyl acetoacetate group having 5 to 30 carbon atoms include, but are not limited to, a methylacetoacetate group, an ethylacetoacetate group, and the like. In terms of synthesis easiness, stability, and the like, the ethylacetoacetate group is preferable.

When L represents aluminum, examples of the metal compound represented by the above formula (2) include aluminum methoxide, aluminum ethoxide, aluminum propoxide, aluminum isopropoxide, aluminum butoxide, aluminum amyloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxyethyl acetoacetate, aluminum dibutoxyethyl acetoacetate, aluminum propoxybis ethylacetoacetate, aluminum butoxybis ethylacetoacetate, aluminum 2,4-pentanedionate, aluminum 2,2,6,6-tetramethyl-3,5-heptanedionate, and the like.

When L represents gallium, examples of the metal compound represented by the above formula (2) include gallium methoxide, gallium ethoxide, gallium propoxide, gallium isopropoxide, gallium butoxide, gallium amiloxide, gallium hexyloxide, gallium cyclopentoxide, gallium cyclohexyloxide, gallium allyloxide, gallium phenoxide, gallium methoxyethoxide, gallium ethoxyethoxide, gallium dipropoxyethyl acetoacetate, gallium dibutoxyethyl acetoacetate, gallium propoxybis ethylacetoacetate, gallium butoxybis ethylacetoacetate, gallium 2,4-pentanedionate, gallium 2,2,6,6-tetramethyl-3,5-heptanedionate, and the like.

When L represents yttrium, examples of the metal compound represented by the above formula (2) include yttrium methoxide, yttrium ethoxide, yttrium propoxide, yttrium isopropoxide, yttrium butoxide, yttrium amyloxide, yttrium hexyloxide, yttrium cyclopentoxide, yttrium cyclohexyloxide, yttrium allyloxide, yttrium phenoxide, yttrium methoxyethoxide, yttrium ethoxyethoxide, yttrium dipropoxyethyl acetoacetate, yttrium dibutoxyethyl acetoacetate, yttrium propoxybis ethylacetoacetate, yttrium butoxybis ethylacetoacetate, yttrium 2,4-pentanedionate, yttrium 2,2,6,6-tetramethyl-3,5-heptanedionate, and the like.

When L represents titanium, examples of the metal compound represented by the above formula (2) include titanium methoxide, titanium ethoxide, titanium propoxide, titanium isopropoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxybis ethylacetoacetate, titanium dibutoxybis ethylacetoacetate, titanium dipropoxybis 2,4-pentanedionate, bis(2,4-pentanedionato) titanium oxide, titanium dibutoxybis 2,4-pentanedionate, and the like.

When L represents zirconium, examples of the metal compound represented by the above formula (2) include methoxy zirconium, ethoxy zirconium, propoxy zirconium, isopropoxy zirconium, butoxy zirconium, phenoxy zirconium, zirconium dibutoxide bis(2,4-pentanedionate), bis(2,4-pentanedionato) zirconium oxide, zirconium dipropoxide bis(2,2,6,6-tetramethyl-3,5-heptanedionate) and the like.

When L represents hafnium, examples of the metal compound represented by the above formula (2) include hafnium methoxide, hafnium ethoxide, hafnium propoxide, hafnium isopropoxide, hafnium butoxide, hafnium amyloxide, hafnium hexyloxide, hafnium cyclopentoxide, hafnium cyclohexyloxide, hafnium allyloxide, hafnium phenoxide, hafnium methoxyethoxide, hafnium ethoxyethoxide, hafnium dipropoxybis ethylacetoacetate, hafnium dibutoxybis ethylacetoacetate, hafnium dipropoxybis 2,4-pentanedionate, hafnium dibutoxybis 2,4-pentanedionate, and the like.

When L represents bismuth, examples of the metal compound represented by the above formula (2) include methoxy bismuth, ethoxy bismuth, propoxy bismuth, isopropoxy bismuth, butoxy bismuth, phenoxy bismuth, and the like.

When L represents tin, examples of the metal compound represented by the above formula (2) include methoxy tin, ethoxy tin, propoxy tin, isopropoxy tin, butoxy tin, phenoxy tin, methoxyethoxy tin, ethoxyethoxy tin, tin 2,4-pentanedionate, tin 2,2,6,6-tetramethyl-3,5-heptanedionate, and the like.

When L represents vanadium, examples of the metal compound represented by the above formula (2) include vanadium oxide bis(2,4-pentanedionate), vanadium 2,4-pentanedionate, vanadium tributoxide oxide, vanadium tripropoxide oxide, and the like.

When L represents tantalum, examples of the metal compound represented by the above formula (2) include methoxy tantalum, ethoxy tantalum, propoxy tantalum, isopropoxy tantalum, butoxy tantalum, phenoxy tantalum, and the like.

A usage amount of the metal compound represented by the above formula (2) is not particularly limited, and is, for example, 30 to 70% by mass, preferably 40 to 60% by mass based on the total amount of components other than the solvent in the metal oxide film-forming composition. When the usage amount of the metal compound is within the above range, the film thickness uniformity of the obtained metal oxide film is easily improved.

### [Solvent]

The metal oxide film-forming composition according to the present invention contains a solvent for the purpose of adjusting the coatability and viscosity. As the solvent, an organic solvent is typically used. There is no particular limitation on types of the organic solvent as long as it can uniformly dissolve or disperse components contained in the metal oxide film-forming composition.

Suitable examples of the organic solvent usable as the solvent include (poly)alkylene glycol monoalkyl ethers such as ethylene glycol monomethyl ether, ethylene glycol monoethyl ether, ethylene glycol n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, 3-heptanone, and acetylacetone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxobutanoate, and cyclohexanol acetate; aromatic hydrocarbons such as toluene and xylene; and amides such as N-methylpyrrolidone, N,N-dimethylformamide, and N,N-dimethylacetamide. These organic solvents can be used alone or in combination of two or more types thereof. For example, acetylacetone may be used in combination with other solvents (e.g., propylene glycol monomethyl ether acetate or cyclohexanol acetate) because the dispersion stability of the obtained metal oxide film-forming composition is further easily improved.

There is no particular limitation on the usage amount of the solvent in the metal oxide film-forming composition according to the present invention. In view of the coatability and the like of the metal oxide film-forming composition, the usage amount of the solvent is, for example, 30 to 99.9% by mass, preferably 50 to 98% by mass based on the entire metal oxide film-forming composition. When acetylacetone is used in combination with another solvent as described above, the content of acetylacetone is preferably 1.5 or more times mole, more preferably 2 or more times mole as much as the metal compound represented by the above formula (2) in terms of the stability of the metal oxide film-forming composition. The upper limit of the content of the acetylacetone only needs to be appropriately adjusted, and it is preferable that the content of the acetylacetone is preferably 50% by mass or less based on the entire solvent contained in the metal oxide film-forming composition in terms of solubility of the organooxy group-containing aromatic hydrocarbon ring-modified fluorene compound represented by the above formula (1).

### [Other Components]

The metal oxide film-forming composition according to the present invention can optionally contain additives such as surfactants (surface conditioner), dispersants, thermal polymerization inhibitors, defoamers, silane coupling agents, colorants (pigments, dyes), inorganic fillers, organic fillers, crosslinking agents, and oxygen generating agents. For all of the additives, a conventionally known additive can be used. Examples of the surfactant include anionic, cationic, and nonionic compounds. Examples of the thermal polymerization inhibitor include hydroquinone, hydroquinone monoethyl ether, and the like. Examples of the defoamer include silicone-based compounds, fluorine-based compounds, and the like.

Examples of the method for producing the metal oxide film-forming composition according to the present invention include, but are not particularly limited to, a method of homogeneously mixing the organooxy group-containing aromatic hydrocarbon ring-modified fluorene compound represented by the above formula (1), the metal compound represented by the above formula (2), a solvent, and optionally other components.

### <Method for Producing Metal Oxide Film>

The method for producing the metal oxide film according to the present invention includes a coating film-forming step of forming a coating film composed of the metal oxide film-forming composition according to the present invention, and a heating step of heating the coating film.

For example, the metal oxide film-forming composition is applied onto a substrate such as a semiconductor substrate to form the coating film. Examples of the coating method include methods using a contact transfer-type coating apparatus such as a roll coater, a reverse coater, and a bar coater, or a non-contacting-type coating apparatus such as a spinner (rotary coating apparatus, spin coater), a dip coater, a spray coater, a slit coater, and a curtain flow coater. After adjusting the viscosity of the metal oxide film-forming composition in an appropriate range, the metal oxide film-forming composition may be applied by a printing method such as an inkjet method and a screen printing method to form a coating film with a desired pattern shape.

The substrate preferably contains a metal film, a metal carbide film, a metal oxide film, a metal nitride film, or a metal oxynitride film. The metal constituting the substrate preferably contains silicon, titanium, tungsten, hafnium, zirconium, chromium, germanium, copper, aluminum, indium, gallium, arsenic, palladium, iron, tantalum, iridium, molybdenum or an alloy thereof, and above all, silicon, germanium and gallium are preferable. In addition, the substrate surface may be uneven, and the uneven shape may be formed from a patterned organic material.

Then, as necessary, a volatile component such as a solvent is removed to dry the coating film. Examples of the drying method include, but are not particularly limited to, a method of drying the coating film with a hot plate at a temperature in a range of 80° C. or higher to 140° C. or lower, preferably 90° C. or higher to 130° C. or lower, for 90 seconds or more to 150 seconds or less. Prior to the heating with the hot plate, reduced pressure drying may be conducted using a vacuum drying device (VCD) at room temperature.

After the coating film is formed in this way, the coating film is heated. The temperature for the heating is not particularly limited, and from the viewpoint of the curability of the coating film, the temperature is preferably 160° C. or higher, more preferably 170° C. or higher, even more preferably 180° C. or higher. The upper limit of the temperature only needs to be set as appropriate, and the temperature only needs to be set to, for example, 600° C. or lower, and in terms of heat resistance, preferably 550° C. or lower, more preferably 500° C. or lower. The heating time is typically 60 seconds or more to 300 seconds or less, more preferably 120 seconds or more to 240 seconds.

The heating steps may be performed at a single heating temperature or may be performed at a plurality of stages of different heating temperatures. For example, from the viewpoint of improving the curability of the coating film, it is allowed to adopt a process, after drying the coating film, first, the first-stage heating is conducted at a heating temperature of preferably 160° C. or higher to 240° C. or lower, more preferably 170° C. or higher to 230° C. or lower, even more preferably 180° C. or higher to 220° C. or lower, preferably for 30 seconds or more and 150 seconds or less, more preferably for 60 seconds or more and 120 seconds or less, and then the second-stage heating is conducted at a heating temperature of preferably 400° C. or higher to 600° C. or lower, more preferably 420° C. or higher to 550° C. or lower, even more preferably 430° C. or higher to 500° C. or lower, preferably for 30 seconds or more and 150 seconds or less, more preferably for 60 seconds or more and 120 seconds or less.

The metal oxide film formed as described above is suitably used, for example, as a metal hard mask or a material for pattern reversal. Preferably, the above metal oxide film has a refractive index of 1.8 or higher at a temperature of 25° C. and a wavelength of 550 nm. Thus, the metal oxide film is suitably used for optical applications requiring a high refractive index. For example, the above metal oxide film is suitably used as a high refractive index film constituting an antireflective film or the like in a display panel such as an organic EL display panel and a liquid crystal display panel.

The film thickness of the above metal oxide film is not particularly limited and may be appropriately selected according to the application. The film thickness may be typically 1 nm or larger to 20 μm or smaller, and 50 nm or larger to 10 μm or smaller.

### EXAMPLES

The present invention will be described below in more detail by way of Examples, but the present invention is not limited to these Examples.

### [Preparation of Metal Oxide Film-Forming Composition]

### (Modified Fluorene Compound)

Preparation of Modified Bisnaphthol Fluorene Compound 1-A

A bisnaphthol fluorene represented by the following formula 7-A was reacted with a di-tert-butyl dicarbonate represented by the following formula 8-A in the presence of N,N-dimethyl-4-aminopyridine in dichloromethane to obtain a modified bisnaphthol fluorene compound 1-A described below.

Preparation of Modified Bisnaphthol Fluorene Compound 1-B

A bisnaphthol fluorene represented by the following formula 7-B was reacted with the di-tert-butyl dicarbonate represented by the following formula 8-A in the presence of N,N-dimethyl-4-aminopyridine in dichloromethane to obtain a modified bisnaphthol fluorene compound 1-B described below.

Preparation of Modified Bisnaphthol Fluorene Compound 1-C

35 g of bisphenol fluorene represented by the following formula 7-B was mixed with 350 g of diethyl ether, and 1 g of p-toluenesulphonic acid was added to the obtained mixture. Subsequently, 15 g of ethyl vinyl ether was added to the mixture at 15° C. to 25° C. for 30 minutes. The mixture was further stirred for 30 minutes, then 5 g of triethylamine was added to the mixture, to which 50 g of a 5 mass % sodium hydroxide aqueous solution was then added, stirred, and allowed to stand, and then liquids were separated. To an obtained organic phase, 100 g of pure water was added, stirred, and allowed to stand, and then liquids were separated. This process was repeated twice. The remaining organic phase was condensed under reduced pressure to obtain 47 g of modified bisphenol fluorene compound 1-C.

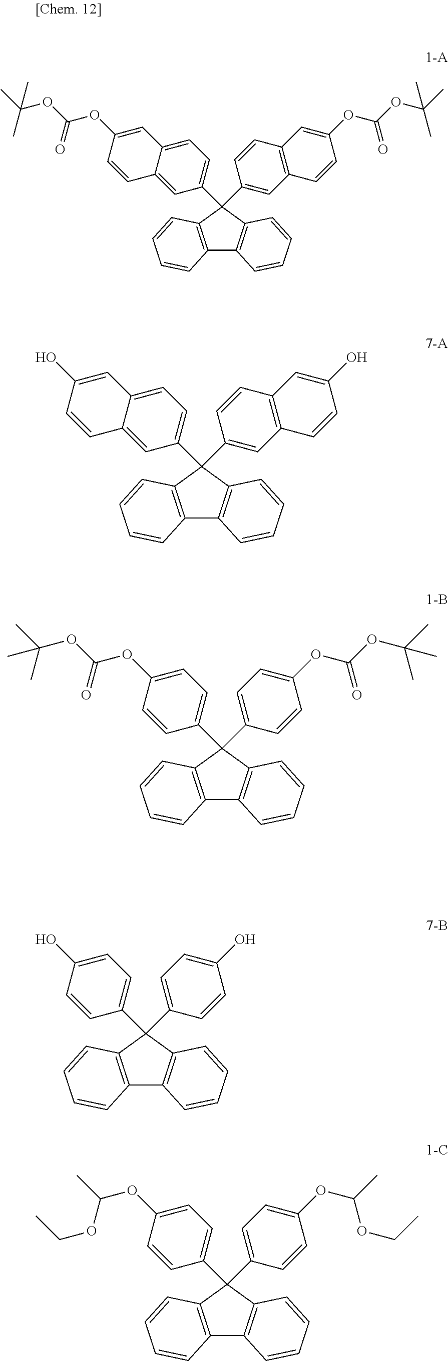

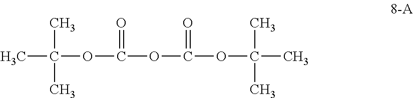

### (Metal Compound)

Ti(OBt)₄: titanium tetrabutoxide
Ti(OiPr)₄: titanium tetraisopropoxide
Ti(acac)₂: bis(2,4-pentanedionato) titanium oxide
Zr(OBt)₄: zirconium tetrabutoxide
Zr(acac)₂: Bis(2,4-pentanedionato) zirconium oxide
Hydrolyzed condensate A mixture of 2.7 g of pure water and 50 g isopropyl alcohol was dripped to a mixture of 28.4 g of titanium tetraisopropoxide, 50 g of isopropyl alcohol, and 11.8 g of 2-(butylamino) ethanol. After termination of the dripping, the mixture was stirred for 2 hours to advance hydrolytic condensation, and then refluxed for another 2 hours. To the resulting reaction mixture, 100 g of propylene glycol monomethyl ether acetate (PGMEA) was added, the mixture was condensed under reduced pressure to obtain 130 g of PGMEA solution of the hydrolyzed condensate. In this solution, a solid concentration of the hydrolyzed condensate was 13.5% by mass.

### (Solvent)

CHXA: Cyclohexanol acetate
Acac: Acetylacetone
PGMEA: Propylene glycol monomethyl ether acetate

A fluorene compound and a metal compound were added to a solvent 1 or a mixture of the solvent 1 and a solvent 2 in types and masses presented in Table 1, stirred, and filtered through a Φ0.2 μm membrane filter to prepare a composition. Note that, in Table 1, the mass of the fluorene compound and the metal compound represent a mass of solid contents.

### [Dispersion Stability]

The composition prepared as described above was visually observed and the dispersion stability of the composition was evaluated in accordance with the following criteria. The results are presented in Table 1. OK (good): No turbidity was observed within 30 minutes after the preparation. NG (poor): Turbidity such as cloudiness was observed within 30 minutes after the preparation.

### [Production of Metal Oxide Film]

The composition was dripped onto a 6-inch silicon wafer, spin-coated, and subsequently pre-baked using a hot plate at 100° C. for 120 seconds, and post-baked at 200° C. for 90 seconds, and further at 450° C. for 90 seconds to obtain a metal oxide film having a thickness of about 60 nm.

### [Film Thickness Uniformity]

Five metal oxide films were produced from the same composition as described above, and their cross sections were observed by SEM to measure their film thicknesses. A fluctuation rate of the film thickness was calculated from a film thickness maximum value Tₘₐₓ, a film thickness minimum value Tₘᵢₙ, and a film thickness mean value Tₘₑₐₙ according to the following equation.

Fluctuation rate of film thickness(%)=(Tₘₐₓ−Tₘᵢₙ)/Tₘₑₐₙ×100

The film thickness uniformity was evaluated in accordance with the following criteria. The results are presented in Table 1.
OK (good): The fluctuation rate of the film thickness was 20% or lower.
NG (poor): The fluctuation rate of the film thickness was higher than 20%.

### [Refractive Index]

The refractive index of the obtained metal oxide film was measured using a spectroscopic ellipsometer (trade name: M-2000, manufactured by J. A. Woollam Japan) at a temperature of 25° C. and a wavelength of 550 nm and evaluated in accordance with the following criteria. The results are presented in Table 1. OK (good): The refractive index was 1.8 or higher.

NG (poor): The refractive index was lower than 1.8.

### [Heat Resistance]

A mass change of the obtained metal oxide film was measured using a thermogravimetric/differential thermal simultaneous measurement apparatus (trade name: STA 449 Jupiter, manufactured by NETZSCH Japan) at 30° C. to 600° C. and a temperature elevation rate of 10° C./min. The heat resistance of the metal oxide film was evaluated in accordance with the following criteria. The results are presented in Table 1. OK

(good): A temperature in 5% weight loss was 450° C. or higher.
NG (poor): A temperature in 5% weight loss was lower than 450° C.

TABLE 1

| | | | | | | | | | Comparative | | |
|---|---|---|---|---|---|---|---|---|---|---|---|
| | Examples | | | | | | | | Examples | | |
| | 1 | 2 | 3 | 4 | 5 | 6 | 7 | 8 | 1 | 2 | 3 |
| Fluorene compound | 1-A | 1-A | 1-A | 1-A | 1-B | 1-A | 1-A | 1-C | — | 7-A | 1-C |
| 0.8 g | | | | | | | | | | | |
| Metal compound | Ti | Ti | Ti | Ti | Ti | Zr | Zr | Ti | Ti | Ti | Hydrolyzed |
| 0.8 g | (OBt)₄ | (OBt)₄ | (OiPr)₄ | (acac)₂ | (acac)₂ | (OBt)₄ | (acac)₂ | (acac)₂ | (OBt)₄ | (OBt)₄ | condensate |
| Solvent 1 | CHXA | CHXA | CHXA | CHXA | PGMEA | CHXA | CHXA | CHXA | CHXA | CHXA | PGMEA |
| 15.2 g | | | | | | | | | | | |
| Solvent 2 | | Acac | | | | | | | | | |
| 0.4 g | | | | | | | | | | | |
| Dispersion | OK | OK | OK | OK | OK | OK | OK | OK | OK | NG | OK |
| stability | | | | | | | | | | | |
| Film thickness | OK | OK | OK | OK | OK | OK | OK | OK | —* | — | NG |
| uniformity | | | | | | | | | | | |
| Refractive | OK | OK | OK | OK | OK | OK | OK | OK | — | — | OK |
| index | | | | | | | | | | | |
| Heat | OK | OK | OK | OK | OK | OK | OK | OK | — | — | OK |
| resistance | | | | | | | | | | | |

*No film could be formed in Comparative Example 1

As can be seen from Table 1, it was confirmed that, in Examples, the compositions were excellent in dispersion stability and the metal oxide films obtained after heating the compositions were excellent in film thickness uniformity, refractive index, and heat resistance, whereas, in Comparative Examples, the compositions were poor in dispersion stability, or the metal oxide films were poor in any of film thickness uniformity, refractive index, and heat resistance.

What is claimed is:

1. A metal oxide film-forming composition comprising: an organooxy group-containing aromatic hydrocarbon ring-modified fluorene compound represented by the following formula (1);
a metal compound represented by the following formula (2); and
a solvent, 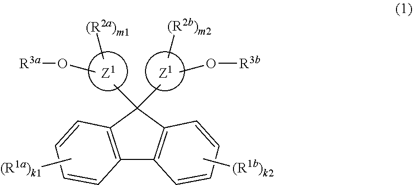
wherein, in formula (1),
ring Z¹ represents an aromatic hydrocarbon ring, R^{1a} and R^{1b} each independently represents a halogen atom, a cyano group, or an alkyl group,
R^{2a} and R^{2b} each independently represents an alkyl group,
R^{3a} and R^{3b} are each independently a group represented by the following formula (3), (4), (5), or (6),
k1 and k2 each independently represents an integer of 0 or larger to 4 or smaller, and
m1 and m2 each independently represents an integer of 0 or larger to 6 or smaller:
L(R⁶)ₙ₁(O)ₙ₂ (2)
wherein, in formula (2), R⁶ represents a group represented by OR⁷, R⁷ represents an organic group having 1 to 30 carbon atoms, and n1 and n2 each independently represent an integer of 0 or larger, provided that n1+2×n2 is a valence depending on the type of L, and L represents aluminum, gallium, yttrium, titanium, zirconium, hafnium, bismuth, tin, vanadium, or tantalum, 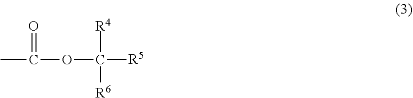
wherein, in formula (3), R⁴, R⁵ and R⁶ each independently represents an alkyl group having 1 to 8 carbon atoms: 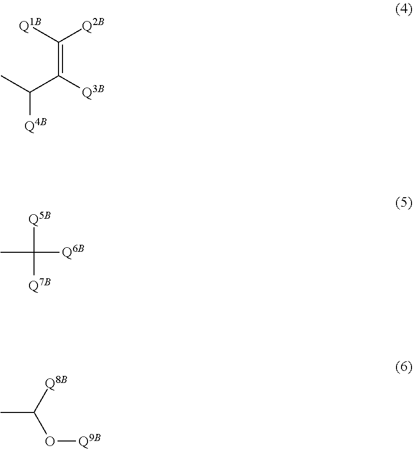
wherein, Q^{1B} to Q^{4B} are each a hydrogen atom or an alkyl group having 1 to 20 carbon atoms, and any two substituents selected from the group consisting of Q^{1B} to Q^{4B} may be bonded to each other to form a cyclic substituent,
Q^{5B} to Q^{7B} are each an alkyl group having 1 to 20 carbon atoms, and any two substituents selected from the group consisting of Q^{5B} to Q^{7B} may be bonded to each other to form a cyclic substituent,
Q^{8B} and Q^{9B} are each an alkyl group having 1 to 20 carbon atoms, and Q^{8B} and Q^{9B} may be bonded to each other to form a cyclic substituent.

2. The metal oxide film-forming composition according to claim 1, wherein the aromatic hydrocarbon ring is a naphthalene ring or a benzene ring.

3. The metal oxide film-forming composition according to claim 1, wherein R^{3a} and R^{3b} are both a group represented by the formula (3).

4. The metal oxide film-forming composition according to claim 1, wherein R⁴, R⁵ and R⁶ are each a methyl group.

5. A method for producing a metal oxide film, comprising:
forming a coating film composed of the metal oxide film-forming composition according to claim 1; and
heating the coating film.
